(19) United States
(12) Patent Application Publication
(10) Pub. No.: US 2007/0099397 A1
(43) Pub. Date: May 3, 2007

(54) Microfeature dies with porous regions, and associated methods and systems

(75) Inventors: Kyle K. Kirby, Eagle, ID (US); Paul A. Morgan, Kuna, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/634,417

(22) Filed: Dec. 4, 2006

Related U.S. Application Data
(62) Division of application No. 10/927,486, filed on Aug. 26, 2004.

(51) Int. Cl. H01L 21/00

(52) U.S. Cl. 438/460

(57) ABSTRACT

Microfeature dies with porous regions, and associated methods and systems are disclosed. A method in accordance with one embodiment of the invention includes forming a porous region between a die and a remainder portion of a microfeature workpiece, and separating the die from the remainder portion by removing at least a portion of the porous region. For example, the die can be removed from the remainder portion by making a cut at the porous region (e.g., with a rotating saw blade), etching material from the porous region, or directing a water jet at the porous region. In other embodiments, a porous region of the microfeature workpiece can receive conductive material to form a conductive pathway (e.g., a line and/or via) in the workpiece. In still further embodiments, the porous regions of the workpiece can be formed electrolytically with electrodes that are spaced apart from the workpiece and/or support relative movement between the electrodes and the workpiece.

### TECHNICAL FIELD

The present invention relates generally to microfeature dies with porous regions, and associated methods and systems, including dies with conductive structures formed from porous media, and methods for singulating dies having porous media.

### BACKGROUND

Packaged microelectronic assemblies, such as memory chips and microprocessor chips, typically include a microelectronic die mounted to a substrate and encased in a plastic protective covering. The die includes functional features, such as memory cells, processor circuits and interconnecting circuitry. The die also typically includes bond pads electrically coupled to the functional features. The bond pads are coupled to pins or other types of terminals that extend outside the protective covering for connecting the die to buses, circuits, and/or other microelectronic assemblies. Alternatively, bare microelectronic dies can be connected to other microelectronic assemblies.

Multiple microelectronic dies are typically formed simultaneously in a single microelectronic workpiece or wafer, and are then singulated or diced to separate the dies from each other and from the remainder of the workpiece. FIG. 1 illustrates a workpiece 10 having multiple die portions 11 that are singulated or diced in accordance with the prior art. Each die portion 11 can include microelectronic features 12, and a scribe area 14 positioned between neighboring die portions 11. Sacrificial test circuitry 13 is typically positioned in the scribe areas 14 and can extend between the microelectronic features 12. The test circuitry 13 includes conductive material 17 formed in and/or on the workpiece 10 during formation of the microelectronic features 12, and is used for diagnostic purposes to determine the quality of the fabrication processes completed on the workpiece 10.

During singulation, a rotating dicing blade 30 is moved downwardly into contact with the workpiece 10 at the scribe area 14 to cut through the workpiece 10 and separate the neighboring die portions 11 from each other. One drawback associated with this method is that the dicing blade 30 can place high lateral stresses on the die portions 11. In particular, the conductive material 17 can adhere to the dicing blade 30 as the dicing blade 30 cuts through the test circuitry 13, effectively widening the dicing blade 30 and increasing the lateral stresses the dicing blade 30 places on the die portions 11. These lateral stresses can cause cracks 16 to form in the scribe area 14. The cracks 16 can propagate into the die portions 11, where they can damage the microelectronic features 12.

One approach to reducing the lateral stresses placed on the workpiece 10 is to provide one or more relief grooves 15 in the scribe area 14. However, the relief grooves 15 may not provide sufficient stress relief to prevent the formation of the cracks 16. Another approach is to increase the width W1 of the scribe area 14 so that any cracks 16 that form in the scribe area 14 do not extend into the microelectronic features 12. A drawback with this approach is that it can significantly reduce the amount of costly workpiece material available for forming the die portions 11.

Another problem associated with existing dies relates to the conductive structures in the dies. Each singulated die typically includes conductive lines and conductive vias that connect microelectronic features 12 within the die. Conductive lines are generally formed in layers of the die oriented generally parallel to the major faces of the die. Conductive vias typically connect conductive lines located in different layers of the die and are therefore oriented generally normal to the major faces of the die. In a typical process, a first set of conductive lines is formed by etching away conductive material in a selected plane of the die. An insulating layer is then disposed over the lines, and conductive vias are formed in the insulating layer. The vias are typically formed by etching holes through the insulating layer, cleaning the holes, coating the holes with a dielectric material, and then filling the holes with a conductive material. Once the vias are formed, an additional plane of conductive material is disposed on the insulating layer, and is selectively etched to form a second set of conductive lines. The second conductive lines are electrically connected to one end of the vias, and the first conductive lines are connected to the other end of the vias. This technique is also used to connect internal vias to external die bond pads. Accordingly, the lines and vias can connect electrical structures spaced laterally apart from each other and/or positioned on different planes of the die.

One drawback associated with the foregoing technique for forming vias in the die is that the technique can be time consuming. Another drawback is that the holes in the vias can provide sites from which cracks can propagate through the die. These cracks can damage other structures (e.g., the microelectronic features 12) within the die.

### BRIEF DESCRIPTION OF THE DRAWINGS

FIG. 1 is a partially schematic, side elevational view of a workpiece being diced in accordance with a prior art method.

FIG. 2 is a partially schematic, cross-sectional view of a microfeature workpiece having a porous region located between die portions, in accordance with an embodiment of the invention.

FIG. 3 is a partially schematic, cross-sectional view of a microfeature workpiece having a porous region sized in accordance with another embodiment of the invention.

FIG. 4 is a partially schematic, side elevation view of a microfeature workpiece having a porous region positioned below test circuitry in accordance with another embodiment of the invention.

FIGS. 5A and 58 illustrate a method for implanting ions during formation of a porous region between die portions of a microfeature workpiece in accordance with an embodiment of the invention.

FIGS. 6A-6F illustrate methods for forming porous material in accordance with further embodiments of the invention.

FIG. 7 is a partially schematic isometric illustration of a singulated die having porous edge surfaces in accordance with an embodiment of the invention.

FIGS. 8A-8D illustrate a process for forming porous regions in a microfeature workpiece in accordance with an embodiment of the invention.

FIGS. 9A-9C illustrate a process for disposing a conductive material in porous regions of a microfeature workpiece, in accordance with an embodiment of the invention.

FIGS. 9D-9E illustrate microfeature dies having conductive paths that include porous regions filled with conductive material, in accordance with another embodiment of the invention.

FIGS. 10A-10F illustrate a process for forming a conductive path in a microfeature workpiece accordance with another embodiment of the invention.

### DETAILED DESCRIPTION

The present invention relates generally to microfeature dies with porous regions, and associated methods and systems. A method for separating a microfeature die in accordance with one aspect of the invention includes forming a porous region between a die and a remainder portion of a microfeature workpiece. The method can further include separating the die from the remainder portion by removing at least a portion of the porous region. For example, at least a portion of the porous region can be removed by making a cut at the porous region, e.g., with a rotating saw blade. In other aspects of the invention, material can be removed using an etching process, or by directing a liquid jet or other ablative stream at the porous region. The microfeature workpiece can have a first surface and a second surface facing away from the first surface, with the porous region extending from the first surface to the second surface, or only part of the distance between the first and second surfaces.

In further particular aspects of the invention, the porous region can be formed by applying an electrical current to the microfeature workpiece in the presence of an electrolyte. For example, the porous region can be formed by positioning a first electrode proximate to and spaced apart from the first surface of the workpiece, disposing an electrolyte between the first electrode and the first surface, and connecting a second electrode directly to the second surface of the workpiece. The method can further include moving at least one of the first electrode and the microfeature workpiece relative to the other while passing a current between the first and second electrodes via the workpiece and the electrolyte.

Aspects of the invention are also directed to a microfeature die. In one aspect of the invention, the microfeature die can include a microfeature workpiece material having a first surface, a second surface facing generally away from the first surface, and an edge surface between the first and the second surfaces. At least part of the edge surface can be porous. The die can further include at least one microelectronic element carried by the microfeature workpiece material.

In further particular aspects of the invention, the edge surface can include a semiconductor material (e.g., silicon), and the porous part of the edge surface can include a porous semiconductor material. At least one microelectronic element can be positioned a first distance from the first surface of the microfeature workpiece material, and the porous part of the edge can extend a second distance from the first surface of the microfeature workpiece, with the second distance being at least as great as the first distance. In still further particular aspects of the invention, the at least one microelectronic element can include at least a portion of a memory circuit, for example, a dynamic random access memory circuit.

Other aspects of the invention are directed toward a method for forming a conductive path in a microfeature workpiece. The method can include forming a porous region in the microfeature workpiece, with the porous region being elongated along an axis. The method can further include disposing a conductive material in pores of the porous region, with the conductive material forming a conductive path between a first point along the axis and a second point along the axis. In yet further aspects of the invention, the conductive material can be insulated from adjacent portions of the microfeature workpiece, for example, by oxidizing surfaces of pores in the porous region. The conductive path can link portions of the workpiece, for example, bond pads located at one or more surfaces of the workpiece.

A microfeature system in accordance with another aspect of the invention includes a microfeature workpiece that has a substrate material with a porous region elongated along an axis, and a conductive material disposed in pores of the porous region to form a conductive path aligned along the axis. The porous region can include a plurality of interconnected pores having interconnected porous surfaces, and the conductive path can include interconnected conductive path segments positioned in the pores. The microfeature workpiece can include a first surface and a second surface facing generally away from the first surface, and the porous region can include a first part extending generally parallel to the first surface and offset from the first surface, and second and third parts that extend generally transverse to the first surface. The first part can be connected to and extend between the second and third parts.

Still further aspects of the invention are directed to methods for processing a microfeature workpiece, and can include disposing ions at a target region of a microfeature workpiece, and disposing an electrolytic liquid in fluid communication with the microfeature workpiece. The method can further include positioning a first electrode in fluid communication with the microfeature workpiece via the electrolytic liquid, and positioning a second electrode in electrical communication with the microfeature workpiece. The method can still further include removing material from the target region to form pores by moving at least one of the first electrode and the microfeature workpiece relative to the other while passing an electrical current along an electrical path that includes the first and second electrodes, the microfeature workpiece, and the electrolytic liquid.

In other embodiments, the second electrode can also be positioned in fluid communication with the workpiece via the electrolytic liquid, and removing material from the target region need not include providing relative movement between the microfeature workpiece and one or more of the electrodes. The resulting porous regions formed in accordance with either of the foregoing methods can be used to aid in separating adjacent die portions, or can be filled or partially filled with conductive material to form a conductive path.

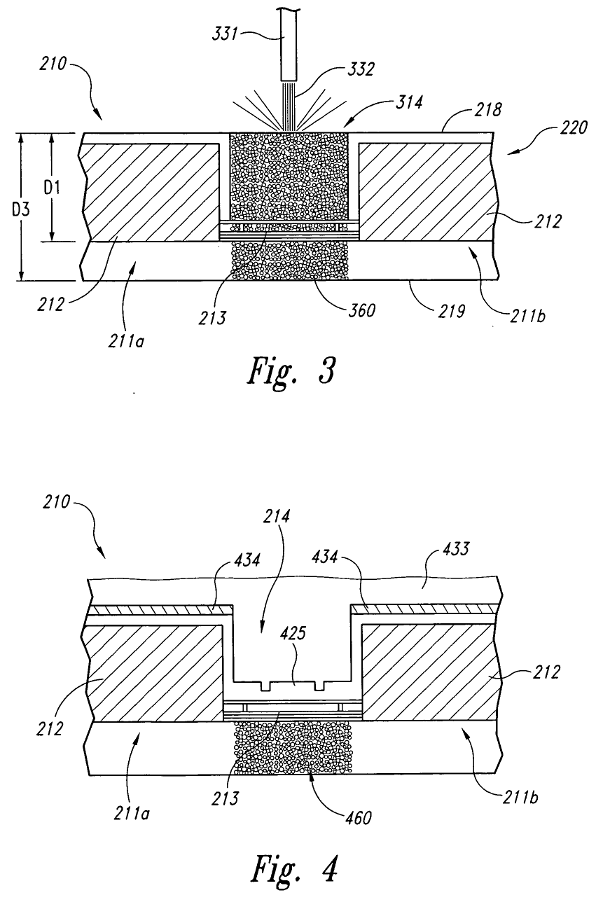

As used herein, the terms “microfeature workpiece” and “workpiece” refer to substrates on and/or in which microelectronic devices are integrally formed. Typical microelectronic devices include microelectronic circuits or components, thin-film recording heads, data storage elements, microfluidic devices and other products. Micromachines and micromechanical devices are included within this definition because they are manufactured using much of the same technology that is used in the fabrication of integrated circuits. The substrates can be semiconductive pieces (e.g., doped silicon wafers or gallium arsenide wafers), nonconductive pieces (e.g., various ceramic substrates) or conductive pieces. In some cases, the workpieces are generally round, and in other cases the workpieces have other shapes, including rectilinear shapes. Several embodiments of systems and methods for separating microfeature workpiece dies, forming porous regions in microfeature workpieces, and forming conductive structures in microfeature workpieces are described below. A person skilled in the relevant art will understand, however, that the invention may have additional embodiments, and that the invention may be practiced without several of the details of the embodiments described below with reference to FIGS. 2-10F.

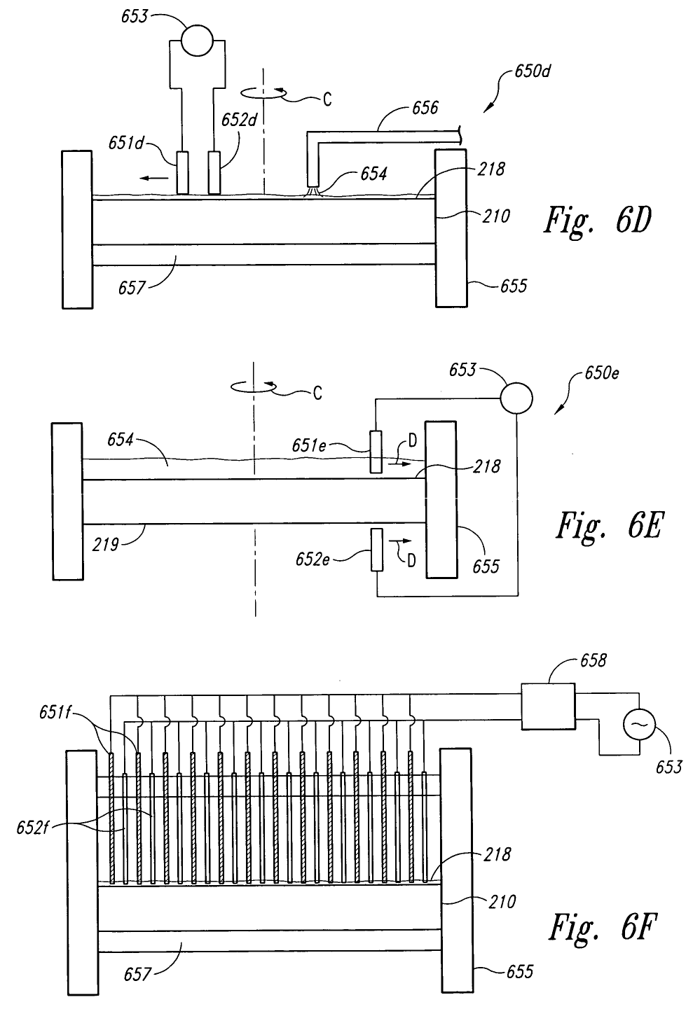

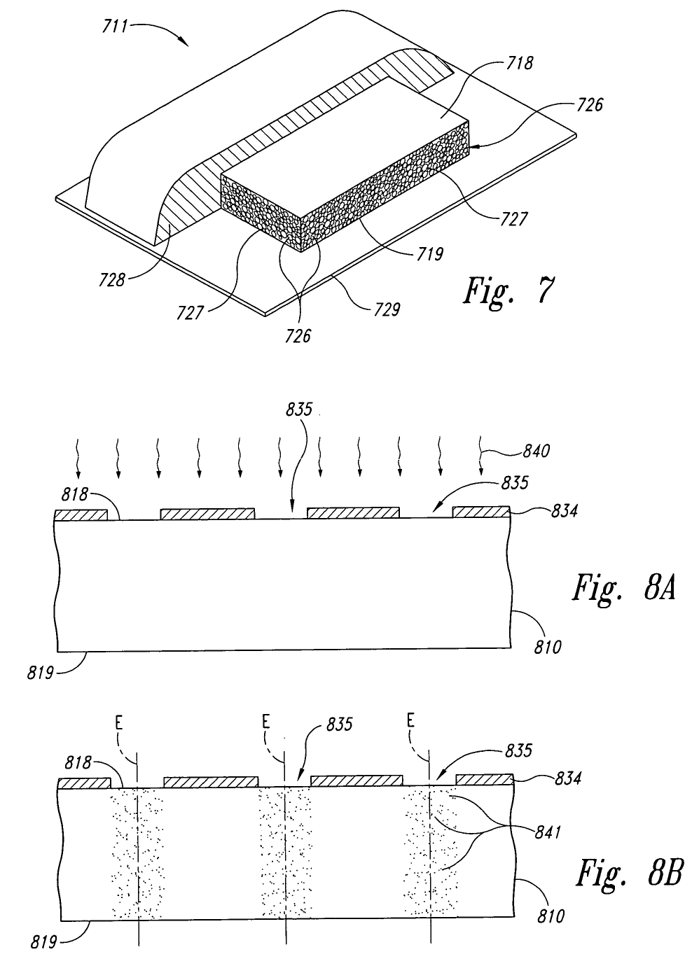

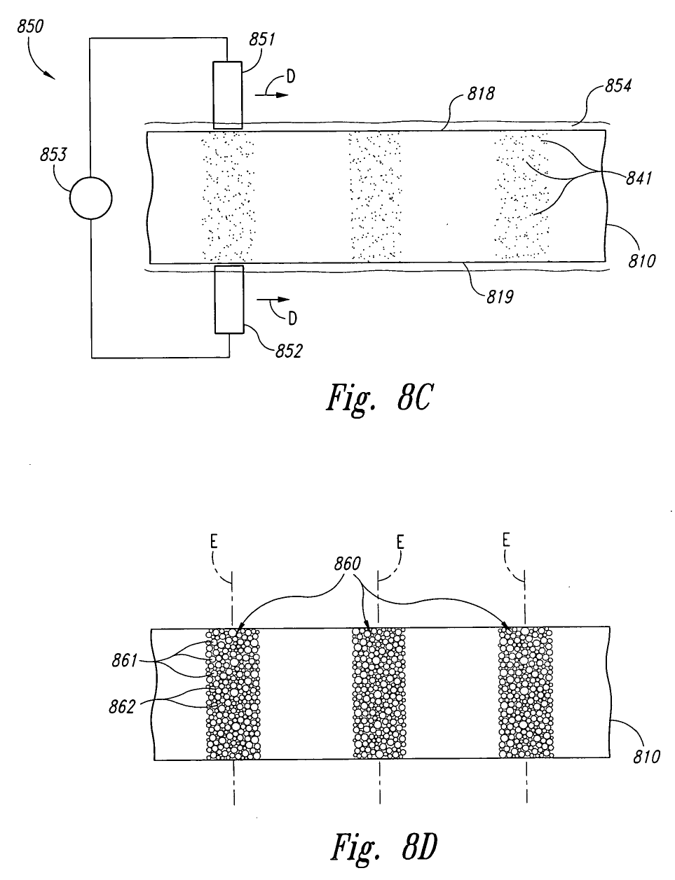

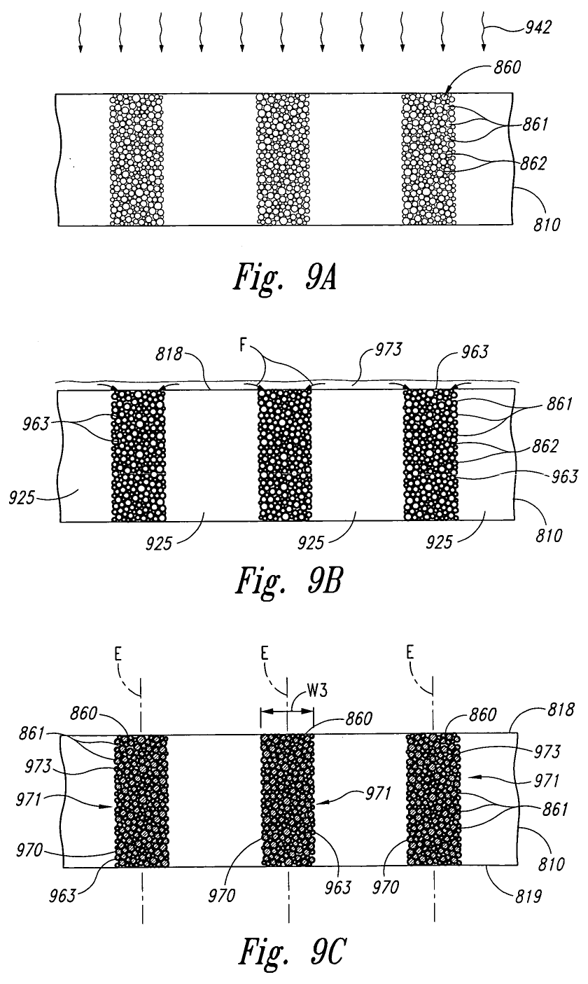

The following description describes porous regions and associated singulation techniques, generally with reference to FIGS. 2-4, and describes methods for forming the porous regions, generally with reference to FIGS. 5A-6F. FIG. 7 describes dies singulated using porous regions, and FIGS. 8A-10E describe workpieces having conductive structures formed using porous regions.

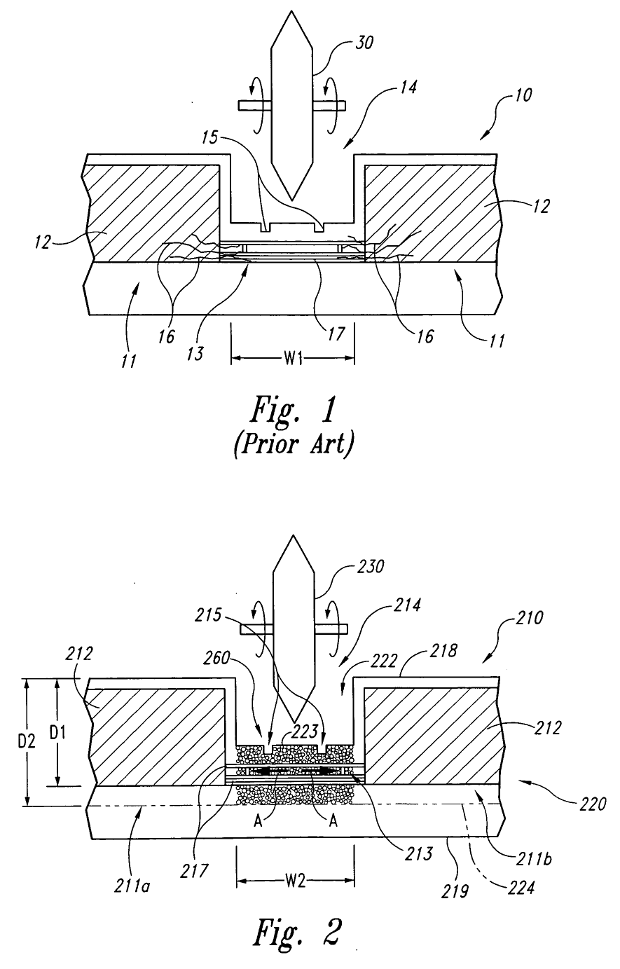

FIG. 2 illustrates a microfeature workpiece 210 having die portions 211 (shown as a first die portion 211a and a second die portion 211b) positioned on opposite sides of a scribe area 214. The microfeature workpiece 210 can also include a porous region 260 that mitigates and/or eliminates the drawbacks associated with singulating or dicing the die portions described above with reference to FIG. 1. Much of the following description associated with FIGS. 2-6F focuses on removing the first die portion 211a from a remainder 220 of the microfeature workpiece 210 that includes the second die portion 211b. The same process can be used to separate the second die portion 211b and other die portions from the microfeature workpiece 210.

The microfeature workpiece 210 can have a first surface 218, a second surface 219 facing away from the first surface 218, and microelectronic features or elements 212 located at the die portions 211, between the first and second surfaces 218, 219. Sacrificial test circuitry 213 can be located in the scribe area 214 between the die portions 211, and can include conductive material 217 (e.g., conductive lines, vias, and/or circuit elements). The test circuitry 213 can be used to perform diagnostic tests on the microfeature workpiece 210 before the die portions 211 are singulated. In a particular embodiment, the scribe area 214 between the die portions 211 is elongated to form a scribe line extending transverse to the plane of FIG. 2, and includes a recess 222 bounded by a recessed surface 223 that optionally includes grooves 215. The porous region 260 can extend from the recessed surface 223, adjacent to the test circuitry 213 to a backgrind plane 224. Accordingly, the porous region 260 in this embodiment can be formed so as to have little or no impact on the efficacy of the test circuitry 213. In another embodiment, the porous region 260 can be formed in the microfeature workpiece 210 only after the test circuitry 213 is no longer needed, for example, when forming the porous region 260 would adversely affect pre-existing test circuitry 213. In a particular aspect of either embodiment, the die portions 211 (and/or the corresponding microelectronic features 212) can extend to a depth D1 from the first surface 218, and the porous region 260 can extend to a depth D2 (greater than D1) from the first surface 218. As will be described below, this arrangement can reduce the likelihood for damaging the die portions 211 during singulation.

Prior to singulation, material is removed from the second surface 219 of the microfeature workpiece 210 until the backgrind plane 224 is exposed (e.g., using an existing backgrind process). During singulation, a rotating dicing blade 230 can be brought into contact with the microfeature workpiece 210 at the porous region 260. At least one of the microfeature workpiece 210 and the rotating dicing blade 230 is moved relative to the other until the dicing blade 230 penetrates through the microfeature workpiece 210 to, or at least proximate to, the backgrind plane 224. At this point, the first die portion 211a can be separated from the remainder 220 of the microfeature workpiece 210. This process can be repeated for other die portions (e.g., the second die portion 211b) of the microfeature workpiece 210 until all the die portions 211 are singulated.

One feature of an arrangement described above with reference to FIG. 2 is that the porous region 260 can be less dense than non-porous constituents of the microfeature workpiece 210, and can extend to a depth D2 beneath the first surface 218 that is greater than the depth D1 to which the microelectronic features 212 extend. Because the porous region 260 has a reduced density, it can more readily absorb stresses placed upon it by the dicing blade 230. For example, if conductive material 217 from the test circuitry 213 adheres to the dicing blade 230 during singulation (effectively widening the kerf of the dicing blade 230), the porous region 260 can collapse or otherwise fail in a lateral direction (indicated by arrows A). Accordingly, the porous region 260 can absorb the lateral stresses introduced by the dicing blade 230 and can reduce or eliminate cracks that might otherwise propagate into the microelectronic features 212.

A further advantage of an arrangement described above with reference to FIG. 2 is that the dicing blade 230 can cut through the reduced density porous region 260 more quickly than it can cut through a conventional, non-porous scribe area. Accordingly, the time required to singulate the die portions 211 can be reduced, thereby increasing the rate at which a manufacturer can produce finished microelectronic products.

Another feature of an arrangement described above with reference to FIG. 2 is that a width W2 of the scribe area 214 and the porous region 260 can be less than the width W1 of an existing scribe area 14 (FIG. 1). The width W2 (which can be on the order of 100 microns or less) may be reduced because the porous region 214 more effectively absorbs lateral stresses introduced by the dicing blade 230 than does the existing, non-porous scribe area 14. An advantage of this feature is that it can increase the area of the microfeature workpiece 210 available for forming die portions 211, thereby increasing the yield associated with each workpiece 210.

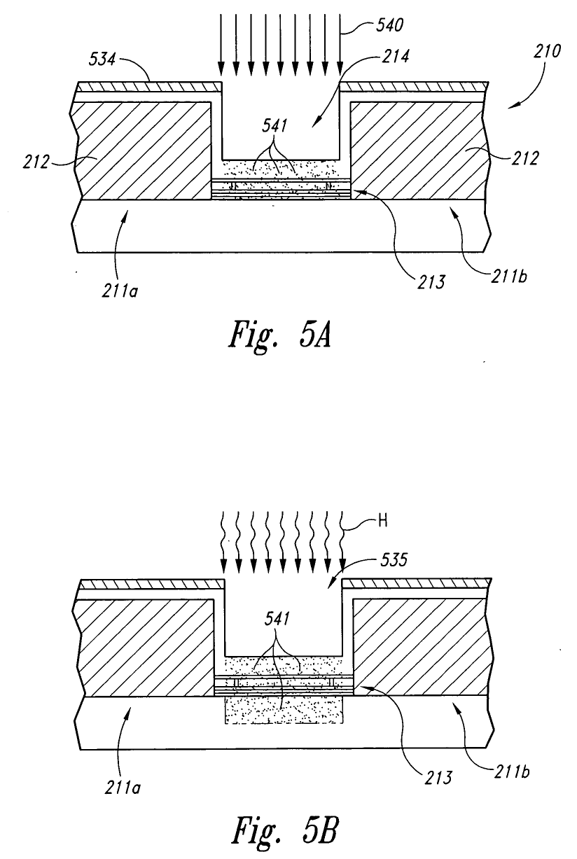

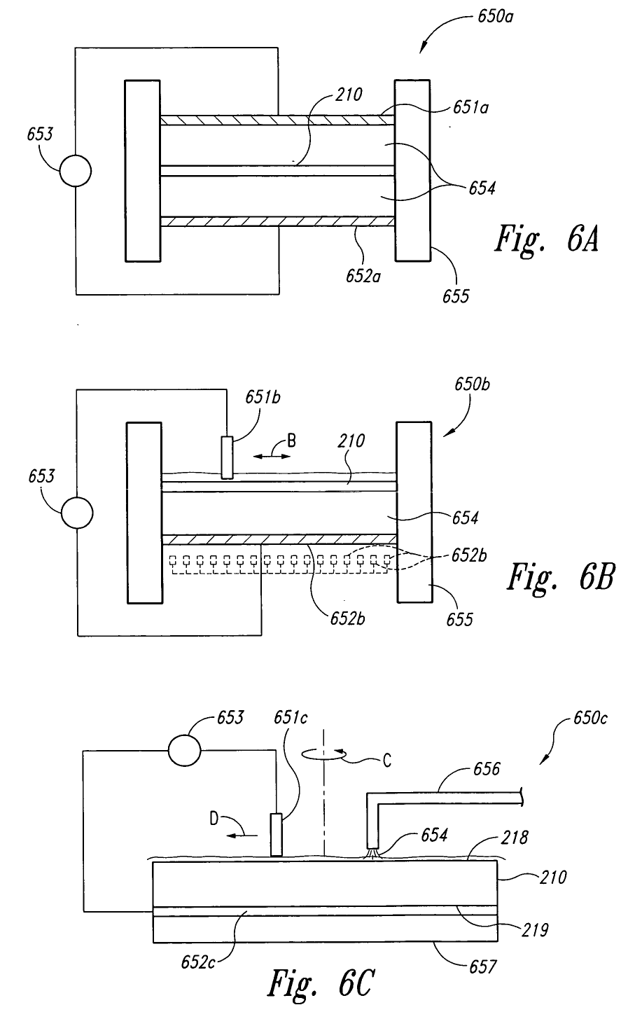

FIGS. 3 and 4 illustrate microfeature workpieces having porous regions arranged differently than the porous region described above with reference to FIG. 2, and also illustrate different techniques for removing material from the porous regions. For purposes of illustration, the techniques for removing material from the porous regions are described in the context of particular porous region arrangements. It will be understood by those of ordinary skill in the relevant art that some or all of the techniques described herein with reference to FIGS. 2-4 for removing material from porous regions can be used with some or all of the porous regions described and shown herein.

Referring now to FIG. 3, the microfeature workpiece 210 can include die portions 211a, 211b spaced apart by a scribe area 314 that is not recessed from the first surface 218. In a further aspect of this embodiment, the microfeature workpiece 210 can include a porous region 360 that extends entirely through the microfeature workpiece 210 from the first surface 218 to the second surface 219. Because the porous region 360 extends entirely through the microfeature workpiece 210, the microfeature workpiece 210 need not be thinned by removing material from the second surface 219 up to a backgrind plane 224 (FIG. 2). Instead, material can be removed from the porous region 360 in a single operation to singulate the first die portion 21 la from the remainder 220 of the microfeature workpiece 210.

In a particular aspect of an embodiment shown in FIG. 3, material can be removed from the porous region 360 with a jet 332 directed toward the microfeature workpiece 210 through a high pressure nozzle 331. The high pressure nozzle 331 can be scanned over the surface of the microfeature workpiece 210 (and/or the microfeature workpiece 210 can be scanned relative to the high pressure nozzle 331) to remove material from the porous region 360 and singulate the first die portion 211a from the remainder 220 of the microfeature workpiece 210. The jet 332 can include one or more liquids (e.g., water and/or an etchant), one or more solids (e.g., sand, dry ice particles, or another particulate), and/or other ablative agents. In another embodiment, the first die portion 211a can be singulated with a laser. As described above with reference to FIG. 2, the porous region 360 can absorb lateral stresses introduced by the jet 332 or other dicing agent, and can accordingly reduce and/or eliminate the formation of cracks in or near the microelectronic features 212. The porous region 360 can also have a reduced width when compared with conventional scribe areas, allowing the die portions 211a, 211b to be positioned more closely together.

FIG. 4 illustrates a microfeature workpiece 210 having a porous region 460 positioned below the test circuitry 213. Accordingly, the porous region 460 can be formed in the microfeature workpiece 210 prior to forming the test circuitry 213. This arrangement can be used when forming the porous region 460 may have an adverse effect on pre-existing test circuitry. In particular, it may be desirable in some cases to form the porous region 460 using a high-temperature process, which may damage pre-existing test circuitry, as well as pre-existing microelectronic features. By forming the porous region 460 prior to forming the test circuitry 213 and the microelectronic features 212, the high temperature process may be conducted without damaging these structures. Alternatively, when it is desirable to form the porous region after forming the test circuitry 213 and/or the microelectronic features 212 (as described above with reference to FIGS. 2 and 3), the porous region can be formed using an equally effective (though perhaps slower) low-temperature process.

In another aspect of an embodiment shown in FIG. 4, material can be removed from the porous region 460 using an etchant 433. The etchant 433 can be disposed on the microfeature workpiece 210, optionally with appropriate masking 434 over the die portions 211a, 211b, to remove material from the scribe area 214, including the porous region 460. If it is too time consuming to remove the non-porous material 425 located in the scribe area 214 over the porous region 460, another technique (e.g., the dicing blade 230 or the water jet 332 described above with reference to FIGS. 2 and 3, respectively) can be used to singulate the die portions 211. Conversely, the etchant 433 shown in FIG. 4 can be used to remove material from the porous regions 221 and 321 (FIGS. 2 and 3, respectively), which have exposed porous surfaces that are directly accessible to the etchant 433. In any of these embodiments, the etchant 433 can include hydrofluoric acid or another substance that includes fluorine and/or a fluorine compound. In still further embodiments, the etchant 433 can include other constituents in addition to or in lieu of fluorine and/or fluorine compounds.

FIGS. 5A and 5B illustrate initial steps for forming a porous region in a microfeature workpiece 210. Referring first to FIG. 5A, the portions of the microfeature workpiece 210 that are to remain non-porous (e.g., the microelectronic features 212), can be protected with a mask 534. An ion beam 540 can then be directed toward the microfeature workpiece 210 to implant ions 541 in the microfeature workpiece 210 (e.g., at the scribe area 214). As shown in FIG. 5B, the ions 541 can be implanted generally directly beneath an opening 535 in the mask 534. The depth to which the ions 541 are implanted can be controlled by controlling the strength of the ion beam 540 and/or the length of time during which the microfeature workpiece 210 is exposed to the ion beam 540, in a manner consistent with techniques generally known to those of ordinary skill in the relevant art. Once the ions 541 are implanted, microfeature workpiece 210 can be annealed by applying heat H to the workpiece 210 and causing the implanted ions 541 to substitute for atoms (e.g., silicon atoms) in the existing lattice structure of the microfeature workpiece 210. The implanted ions 541 can include boron, arsenic, phosphorous or other elements. The ion concentration and temperature at which the workpiece 210 is annealed can determine or at least influence the porosity of the resulting porous region, as can additional factors described below with reference to FIGS. 6A-6F.

FIGS. 6A-6F illustrate techniques for electrolytically forming the porous regions in the microfeature workpiece 210. Beginning with FIG. 6A, the microfeature workpiece 210 having implanted ions can be positioned in an electrolytic cell or chamber 655 of an electrolytic system 650a. The electrolytic cell 655 can be filled with an electrolyte 654 (e.g., alcohol and hydrofluoric acid) and can include a first electrode 651a spaced apart from a second electrode 652a, with the microfeature workpiece 210 positioned between the two electrodes 651a, 652a. The electrodes 651a, 652a can be coupled to a potential source 653 (e.g., a source of varying current, including an AC power source). When the potential source 653 drives the first electrode 651a and the second electrode 652a to different electrical potentials, the resultant current flowing through the electrolyte 654 and the microfeature workpieces 210 removes material from the microfeature workpieces 210 at the sites of the implanted ions, causing the implanted region to become porous. The removed material can include both the implanted ions and (optionally) at least some surrounding workpiece material. The sizes of the pores, and therefore the overall porosity of the porous regions can be controlled by controlling factors that include the current level, current density, time of exposure and/or electrical potential of the electrical signal passing through the electrolyte 654. The porosity can also be controlled by the type of ion implanted in the microfeature workpieces 210, the composition of the electrolyte 654, and/or other factors that are commonly selected for electrolytic processing.

FIG. 6B illustrates an electrolytic system 650b configured in accordance with another embodiment of the invention in which a first electrode 651b is spaced apart from a microfeature workpieces 210, and a second electrode 652b has a fixed position in the electrolytic cell 655. Alternatively, the second electrode 652b can be replaced with a plurality of second electrodes 652b (shown in phantom lines) to form a “bed-of-nails” arrangement. In either embodiment, the first electrode 651b can scan in two orthogonal directions, one of which is indicated by arrow B and the other of which is transverse to the plane of FIG. 6B. Accordingly, the current provided by the potential source 653 can be precisely directed to specific portions of the microfeature workpieces 210, if desired. This arrangement can also provide for locally high current densities over portions of, or the entirety of, the microfeature workpieces 210, without providing a high current density throughout the entire electrolytic cell 655.

FIG. 6C illustrates an electrolytic system 650c having a first electrode 651c positioned proximate to the first surface 218 of the microfeature workpiece 210, and a second electrode 652c attached directly to the second surface 219 of the microfeature workpiece 210. Accordingly, the second surface 219 can have a conductive layer that provides a current path between the second electrode 652c and the interior portion of the microfeature workpiece 210. The microfeature workpiece 210 can be supported on a rotating chuck 657. Both electrodes 651c, 652c can be coupled to opposing poles of the potential source 653, and the electrolyte 654 can be supplied to the first surface 218 via an electrolytic fluid supply line 656. While the microfeature workpiece 210 is rotated (as indicated by arrow C), the first electrode 651c can be moved radially relative to the first surface 218 (as indicated by arrow D) to scan the first electrode 651c over the first surface 218. Accordingly, the two electrodes 651c, 652c can electrolytically form porous regions in the microfeature workpiece 210. In one aspect of this embodiment, this arrangement can be used with a microfeature workpiece 210 having implanted regions or other conductive structures that extend entirely through the microfeature workpiece 210 from the first surface 218 to the second surface 219. Accordingly, the first electrode 651c can provide direct electrical communication with these structures by direct electrical contact with the second surface 219.

FIG. 6D illustrates an electrolytic system 650d having a first electrode 651d and a second electrode 652d, both of which are spaced apart from the microfeature workpiece 210. In one aspect of this embodiment, both the first electrode 651d and the second electrode 652d can be positioned proximate to the first surface 218 of the microfeature workpieces 210 and scanned (as indicated by arrow D) while the microfeature workpiece rotates (as indicated by arrow C). This arrangement can be used with microfeature workpieces 210 having conductive structures and/or ion implanted regions that do not extend entirely through the workpiece to the second surface 219.

FIG. 6E illustrates an electrolytic system 650e having a first electrode 651e positioned proximate to and spaced apart from the first surface 218 of the microfeature workpiece 210, and a second electrode 652e positioned proximate to and spaced apart from the second surface 219. The first and second electrodes 651e, 652e can be scanned together as indicated by arrow D while the microfeature workpiece 210 rotates, as indicated by arrow C. This arrangement can be employed with microfeature workpieces 210 having conductive structures and/or ion implanted regions that extend from or proximate to the first surface 218 to or proximate to the second surface 219.

FIG. 6F illustrates still another electrolytic system 650f having a “bed of nails” arrangement for which electrodes can be selectively powered or unpowered, and can be selectively coupled to one pole or the other of the potential source 653. The system 650f can include a plurality of first electrodes 651f, a plurality of second electrodes 652f, and a controller 658 (e.g., a multiplexer) coupled between the electrodes 651f, 652f and the potential source 653. An operator (or an automated program) can direct the controller 658 to couple members of selected pairs of electrodes 651f, 652f to opposite poles of the potential source 653 for selectively forming porous regions in the workpiece 210. Accordingly, the array of electrodes 651f, 652f can extend transverse to the plane of FIG. 6F to cover some or all of the workpiece 210. This arrangement can allow the electrolytic system 650f to handle workpieces 210 having a wide variety of patterns of porous regions. The electrodes 651f, 652f can be positioned adjacent to the first surface 218 of the workpiece 210, and/or the second surface 219.

Once the pores are formed in the microfeature workpieces 210 (using, for example, any of the methods described with reference to FIGS. 6A-6F), the microfeature workpieces 210 can be cleaned and dried. The surfaces of the porous regions within the microfeature workpieces 210 can optionally be oxidized, using a high temperature or low temperature oxidation process in which the microfeature workpieces 210 are exposed to oxygen, water and/or other oxidizing agents. One advantage of oxidizing the surfaces of the pores is that it can make some dicing processes (e.g., those that employ a wet etch) more effective because the etchant can be chosen to selectively remove oxides. Even when an etching process is not used for dicing, the oxide can form an amorphous layer that resists crack propagation. After the pores have been oxidized, the dies adjacent to the porous regions can be singulated, using any of the processes described above with reference to FIGS. 2-4. Once the dies have been singulated in accordance with any of the foregoing methods, they can be encapsulated and/or otherwise packaged and provided with external contacts (e.g., pins and/or bond pads) in accordance with conventional methods.

FIG. 7 illustrates a singulated die 711 having a first surface 718 and a second surface 719 facing opposite from the first surface 718. The die 711 further includes edge surfaces 726 positioned between the first surface 718 and the second surface 719. The edge surfaces 726 can include residual porous material 727, which remains after the singulation processes described above are completed. In one aspect of this embodiment, the residual porous material 727 can extend over the entire distance between the first surface 718 and the second surface 719, for example, when the porous region extends from the first surface 218 to the second surface 219 of the corresponding microfeature workpiece 210 (e.g., as shown in FIG. 3), and/or when any non-porous regions adjacent to the porous regions are removed (e.g., by backgrinding, as shown in FIG. 2). In other embodiments, the residual porous material 727 can extend over only part of the distance between the first surface of 718 and the second surface 719 of the die 711 (e.g., as shown in FIG. 4). The die 711 can be positioned on a support member 729 and encapsulated with an encapsulant 728, which is partially cut away for purposes of illustration. The die 711 can include a memory device (e.g., a dynamic random access memory (DRAM) device) having multiple memory circuits. In other embodiments, the die 711 can include other circuit structures performing other functions.

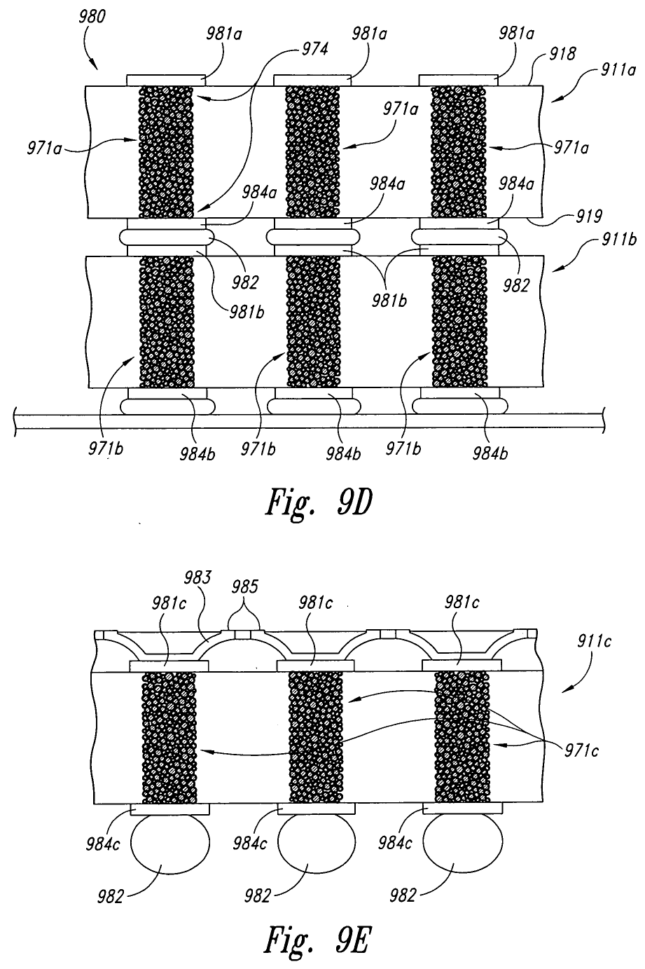

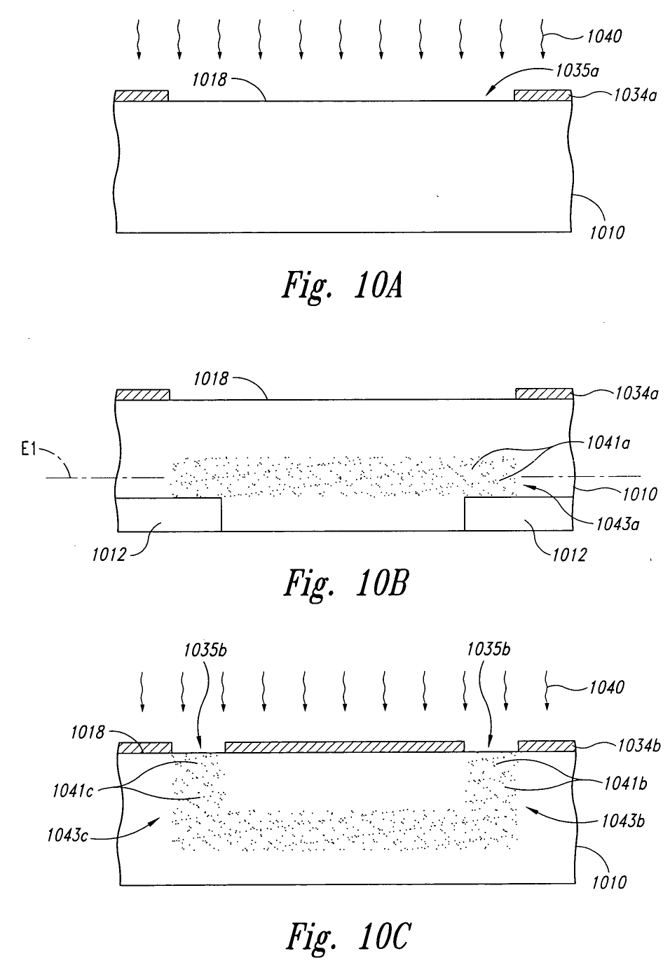

Whether or not the die 711 is singulated by removing porous material, the die can include conductive structures that are formed with porous material. FIGS. 8A-8D illustrate a process for forming porous regions in a microfeature workpiece, and FIGS. 9A-9C illustrate a process for forming conductive pathways in the porous regions, in accordance with embodiments of the invention. These techniques can be used in lieu of the existing etching and filling techniques, and can be less time consuming to implement than existing techniques. The resulting structures can be more robust than existing structures, which can in turn improve the reliability of the devices formed from the microfeature workpieces.

FIG. 8A illustrates a portion of a microfeature workpiece 810 having a first surface 818 and a second surface 819 facing away from the first surface 818. A mask 834 can be positioned adjacent to the first surface 818, and can include mask apertures 835 located at selected regions of the microfeature workpiece 810 at which conductive structures are to be positioned. The masked microfeature workpiece 810 is then exposed to an ion beam 840 to implant ions within the workpiece 810, between the first surface 818 and the second surface 819.

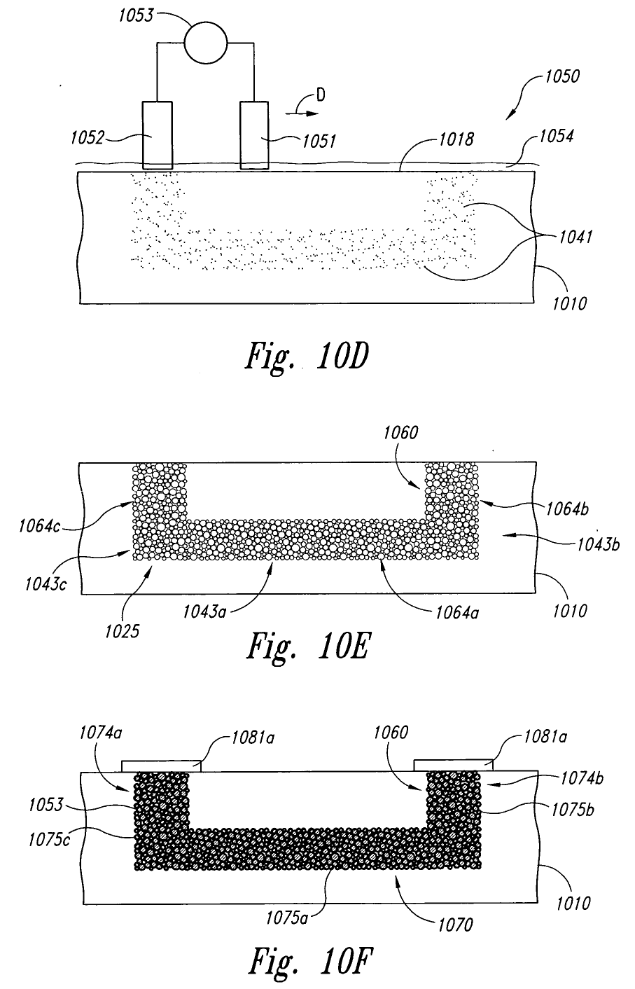

FIG. 8B illustrates the microfeature workpiece 810 after it has been exposed to the ion beam 840 for a selected period of time. Implanted ions 841 are now located beneath the first surface 818 of the workpiece 810, and are aligned with the mask apertures 835 along corresponding axes E. In a particular embodiment, the implanted ions 841 can extend entirely through the microfeature workpiece 810 from the first surface 818 to the second surface 819. In other embodiments (e.g., as described in greater detail below with reference FIGS. 10A-10F), the implanted ions can extend through less than the entire thickness of the microfeature workpiece 810. In any of these embodiments, the implanted ions 841 can be inserted directly into the lattice structure of the microfeature workpiece 810, as described above.

FIG. 8C illustrates a process for forming pores from the implanted ions 841. In one aspect of this process, an electrical charge is applied to the ions 841 via an electrolytic system 850 that is generally similar to the system 650e described above with reference to FIG. 6E. The electrolytic system 850 can include a potential source 853 coupled to a first electrode 851 (located proximate to and spaced apart from the first surface 818 of the microfeature workpiece 810) and a second electrode 852 (located proximate to and spaced apart from the second surface 819 of the microfeature workpiece 810). An electrolyte 854 provides fluid and electrical communication between the microfeature workpiece 810 and the electrodes 851, 852. As the electrodes 851, 852 are scanned over the microfeature workpiece 810, the electrical current provided by the potential source 853 removes the ions located between the first and second surfaces 818, 819 and optionally removes at least some adjacent workpiece material (e.g., silicon) as well.

The foregoing electrolytic process forms porous regions 860, shown in FIG. 8D. Each of the porous regions 860 can include a plurality of pores 861 having pore walls 862. The pores 861 are interconnected with each other so that each porous region 860 has a fluid path aligned with a corresponding one of the axes E.

In other embodiments, the porous regions 860 can be formed using techniques other than those described above with references to FIGS. 8A-8D, for example, those described above with reference to FIGS. 6A-6D and 6F. In any of these embodiments, it may be desirable to electrically isolate the interiors of the porous regions 860 from the rest of the microfeature workpiece 810. One technique for performing this function is shown in FIG. 9A. The microfeature workpiece 810 is exposed to a oxidizing agent 942, which penetrates the pores 861. The oxidizing agent 942 oxidizes the surfaces of the pore walls 862, forming an oxide layer 963, as shown in FIG. 9B. Accordingly, each of the pores 861 can have a surface formed from part of the oxide layer 963, effectively isolating the interior of each porous region 860 from adjacent non-porous regions 925 of the microfeature workpiece 810.

In other embodiments, other techniques can be used to electrically isolate the porous regions 860 from the adjacent non-porous regions 925. For example, a jacket or section of cladding can be inserted around the porous regions 860 to provide such isolation. In another embodiment, a liquid dielectric material can be introduced into the pores 861. This method may be suitable when the pores 861 are relatively large, so that the dielectric material coats the walls of the pores 861 rather than entirely filling the pores 861. In any of these embodiments, the interior regions of the pores 861 can be filled with a conductive material 973 to provide a conductive path 970 through each porous region 860. For example, as shown in FIG. 9B, the conductive material 973 can include a liquid that is positioned adjacent to the first surface 818 of the microfeature workpiece 810. The liquid conductive material 973 can wick into the pores 861 of the porous regions 860, under the influence of capillary forces to infiltrate most or all of the pores 861 as indicated by arrows F. In particular embodiments, the conductive material 973 is selected to include at least one of silver, copper, tungsten, aluminum, tin and lead.

FIG. 9C illustrates the microfeature workpiece 810 after the conductive material 973 has been introduced into the porous regions 860. The conductive material 973 forms corresponding conductive paths 970 at each of the porous regions 960, with each conductive path 970 aligned along ones of the axes E. In the example shown in FIG. 9C, the conductive paths 970 can include conductive vias 971 extending from the first surface 818 of the microfeature workpiece 810 to the second surface 819. Each conductive path 970 can include a multitude of interconnected conductive path segments formed in the corresponding interconnected network of pores 861. Each conductive via 971 as a whole can be electrically isolated from the rest of the microfeature workpiece 810 by the oxide layer 963 at the outer periphery of the corresponding porous region 860. The diameter or width W3 of each conductive via 971 can be selected based on factors that include the electrical current load expected to be carried by the vias 971. For example, vias 971 carrying a relatively low amount of current can have a width W3 of one micron or less.

In other embodiments, other techniques can be used to dispose the conductive material 973 in the porous regions 860. For example, the conductive material 973 can be introduced into the pores 861 while in a gaseous state, e.g., using a vapor deposition process. In one embodiment, the pores 861 are exposed to phosphene gas, or a mixture containing phosphene gas (e.g., 95% nitrogen, 5% phosphene). The microfeature workpiece 810 is then elevated in temperature (e.g., to about 800° C.), causing the phosphene to adsorb to the surfaces of the pores 861.

FIG. 9D illustrates portions of two microfeature dies 911 (shown as a first die 911a and a second die 911b) having conductive features formed in accordance with an embodiment of the invention, and joined to provide electrical communication between the two dies 911. The microfeature dies 911 can include memory chips in one embodiment, and can include other devices (e.g., processor chips) in other embodiments. The first die 911a can include first conductive vias 971a extending between the first surface 918 and the second surface 919 of the first die 911a. The first conductive vias 971a can be coupled to conductive elements 980, e.g., first upper bond pads 981a at the first surface 918, and first lower bond pads 984a at the second surface 919. Accordingly, the first bond pads 981a, 984a can be attached to corresponding end regions 974 of the first conductive vias 971a. The second die 911b can include corresponding second conductive vias 971b electrically connected to corresponding second upper bond pads 981b and second lower bond pads 984b.

The first die 911a can be joined to the second die 911b with solder or another conductive material connected between the first lower bond pads 984a of the first die 911a and the second upper bond pads 981b of the second die 911b. For example, as shown in FIG. 9D, a plurality of reflowed solder balls 982 can provide electrical and physical connections between the first die 911a and the second die 91lb. In this manner, the dies 911a, 911b can be stacked one above the other and can communicate electrically with one another as a result of the electrical connections between the first vias 971a and the second vias 971b. Each stack of dies can include two dies 911 (as shown in FIG. 9D) or more dies in other embodiments. In any of these embodiments, an advantage of this arrangement is that the stacked dies 911 can occupy less surface area of a substrate printed circuit board 929 or other support member upon which they are positioned.

FIG. 9E illustrates a portion of another microfeature die 911c having conductive vias 971c extending between upper bond pads 981c and lower bond pads 984c. A redistribution layer 983 can be connected between the upper bond pads 981c and outer layer bond pads 985. Solder balls 982 can provide for electrical contact with external devices located proximate to the second surface 918 of the die 911c, and the outer layer bond pads 985 can provide electrical contact with external devices located proximate to the first surface 918. In other embodiments, the dies 911a-911c described above can have other arrangements.

FIGS. 10A-10F illustrate a process for forming conductive structures that are buried in a microfeature workpiece 1010 in accordance with an embodiment of the invention. Referring first to FIG. 10A, a first mask 1034a is positioned adjacent to a first surface 1018 of the workpiece 1010. The first mask 1034a includes a first mask aperture 1035a aligned with a target location for a buried conductive structure. An ion beam 1040 is directed toward the microfeature workpiece 1010 to implant ions in the workpiece 1010. The strength of the ion beam 1040 and the duration for which the workpiece 1010 is exposed to the ion beam 1040 can determine the maximum depth to which ions are implanted, and the extent to which the ions extend upwardly from the maximum depth toward the first surface 1018 of the workpiece.

FIG. 10B illustrates the microfeature workpiece 1010 after first ions 1041a are implanted at a first implantation site 1043a. In one aspect of this embodiment, the first implantation site 1043a can be elongated along an axis E1 oriented generally parallel to the first surface 1018, and in other embodiments, the first implantation site 1043a can have other orientations. In one embodiment, the first implantation site 1043a alone determines the extent of a corresponding conductive portion (described below with reference to FIG. 10E) and accordingly, the entire conductive portion can be buried beneath the first surface 1018. The conductive portion can couple two or more buried conductive elements 1012 (e.g., operable microelectronic structures, shown schematically in FIG. 10B), that are already formed in the workpiece 210 at points along the axis E1.

In another embodiment, the conductive portion can couple other conductive portions and/or other conductive elements that are formed in a subsequent process. For example, as shown in FIG. 10C, a second mask 1034b can be positioned proximate to the first surface 1018 of the microfeature workpiece 1010, and can include second mask apertures 1035b. In one aspect of this embodiment, the second mask apertures 1035b can be aligned with end regions of the first implantation site 1043a. Accordingly, when the ion beam 1040 is directed toward the microfeature workpiece 1010 with the second mask 1034b in place, the first implantation site 1043a can be protected while second implanted ions 1041b are implanted at a second implantation site 1043b extending from the first surface 1018 to the first implantation site 1043a. Third implanted ions 1041c can be simultaneously implanted at a third implantation site 1043c located toward the opposite end of the first implantation site 1043a.

FIG. 10D illustrates a process for activating the implanted ions 1041 using an electrolytic system 1050 that is generally similar to the system 650d described above with reference to FIG. 6D. Accordingly, the electrolytic system 1050 can include a first electrode 1051 and a second electrode 1052 that are both positioned proximate to the first surface 1018. The first and second electrodes 1051, 1052 can be moved relative to the microfeature workpiece 1010 (as indicated by arrow D) while providing electrical current to the microfeature workpiece 1010 via an electrolyte 1054.

Referring now to FIG. 10E, the electrical current can activate the implanted ions and form a porous region 1060 that includes a first porous portion 1064a at the first implantation site 1043a, a second porous portion 1064b at the second implantation site 1043b, and a third porous portion 1064c at the third implantation site 1043c, the porous region 1060 can be electrically isolated from the surrounding, nonporous regions 1025 of the microfeature workpiece 1010 by forming an oxide layer in a manner generally similar to that described above with reference to FIG. 9B.

As shown in FIG. 10F, a conductive material 1053 can then be disposed in the porous region 1060 to form a conductive path 1070. The conductive path 1070 can include a first conductive portion 1075a (e.g., a line), a second conductive portion 1075b (e.g., a via), and a third conductive portion 1075c (e.g., another via). Bond pads 1081a, 1081b can be attached to end regions 1074a, 1074b of the conductive portions 1075c, 1075b, respectively. Accordingly, the bond pads 1074a, 1074b can provide for electrical communication between devices external to the workpiece 1010 and electrical features, devices and/or elements internal to the workpiece 1010.

One feature of embodiments of the conductive paths described above with reference to FIGS. 8A-10F is that they can be formed in porous regions of an otherwise generally nonporous substrate material (e.g., crystal silicon). This is unlike existing conductive structures formed in microfeature workpieces, which typically include a hole formed in the substrate, generally without regard for the crystal structure of the substrate. One advantage of at least some of the embodiments described above is that the walls of the pores in the porous region can provide more structural support than is provided by a conventional hole. Accordingly, the microfeature workpiece can be less likely to fail than would be an existing workpiece having relatively large holes extending through portions of the workpiece to accommodate conductive vias or other structures. Another advantage of the foregoing features is that porous regions that are integrated with the existing lattice structure of the microfeature workpiece can be less likely to disrupt the existing crystal structure of the workpiece, and can accordingly be less likely to cause the workpiece to fail, structurally and/or electrically.

From the foregoing, it will be appreciated that specific embodiments of the invention have been described herein for purposes of illustration, but that various modifications may be made without deviating from the spirit and scope of the invention. For example, aspects described in the context of particular embodiments can be combined or eliminated in other embodiments. Accordingly, the invention is not limited except as by the appended claims.

1-99. (canceled)

100. A microfeature die, comprising:
a microfeature workpiece material having a first surface, a second surface facing generally away from the first surface, and an edge surface between the first and second surfaces, at least part of the edge surface being porous; and
at least one microelectronic element carried by the microfeature workpiece material.

101. The microfeature die of claim 100 wherein the edge surface includes a semiconductor material and wherein the porous part of the edge surface includes a porous semiconductor material.

102. The microfeature die of claim 100 wherein the edge surface includes silicon and wherein the porous part of the edge surface includes porous silicon.

103. The microfeature die of claim 100 wherein the porous part of the edge surface is oxidized.

104. The microfeature die of claim 100, further comprising an encapsulant positioned adjacent to the edge surface.

105. The microfeature die of claim 100 wherein the at least one microelectronic element is positioned a first distance from the first surface of the microfeature workpiece material, and wherein the porous part of the edge extends a second distance from the first surface of the microfeature workpiece, the second distance being at least as great as the first distance.

106. The microfeature die of claim 100 wherein the porous part of the edge surface extends from the first surface of the microfeature workpiece to the second surface of the microfeature workpiece.

107. The microfeature die of claim 100 wherein the at least one microelectronic element includes at least a portion of a memory circuit.

108. The microfeature die of claim 100 wherein the at least one microelectronic element includes at least a portion of a dynamic random access memory circuit.

109. A microfeature system, comprising:
a microfeature workpiece that includes:
a substrate material having a porous region elongated along an axis; and
a conductive material disposed in pores of the porous region to form a conductive path aligned along the axis.

110. The system of claim 109, further comprising an insulating material at the surfaces of pores in the porous region.

111. The system of claim 109 wherein the porous region includes a plurality of interconnected pores having interconnected pore surfaces, and wherein the microfeature workpiece further comprises an oxide layer at the pore surfaces.

112. The system of claim 109 wherein the porous region includes a plurality of interconnected pores having interconnected pore surfaces, and wherein the conductive path includes interconnected conductive path segments positioned in the pores.

113. The system of claim 109 wherein the substrate material includes silicon, and wherein the porous region includes porous silicon.

114. The system of claim 109, further comprising:
a bond pad; and
a microelectronic structure disposed in the substrate material, and wherein the conductive path is electrically connected to the microelectronic structure and the bond pad.

115. The system of claim 109, further comprising a bond pad coupled to the conductive path.

116. The system of claim 109 wherein the conductive path includes a first end region and a second end region, and wherein the system further comprises:
a first conductive element coupled to the conductive path toward the first end region; and
a second conductive element coupled to the conductive path toward the second end region.

117. The system of claim 109 wherein the microfeature workpiece includes a first surface and a second surface facing opposite from the first surface, and wherein the conductive path extends through the microfeature workpiece from the first surface to the second surface.

118. The system of claim 109 wherein the microfeature workpiece includes a first microelectronic die, and wherein the system further comprises a second microelectronic die stacked on the first microelectronic die and electrically coupled to the conductive path of the first microelectronic die.

119. The system of claim 109 wherein the conductive material includes at least one of silver, copper, tin, lead, tungsten and aluminum.

120. The system of claim 109 wherein the microfeature workpiece has a first surface, a second surface facing away from the first surface and an edge surface between the first and second surfaces, and wherein the porous region extends away from the first surface and has a dimension generally parallel to the first surface of one micron or less.

121. The system of claim 109 wherein the microfeature workpiece includes a first surface and a second surface facing generally away from the first surface, and wherein the porous region includes:
a first part extending generally parallel to the first surface and offset from the first surface; and
second and third parts that extend generally transverse to the first surface, with the first part connected to and extending between the second and third parts.

122. The system of claim 109 wherein the microfeature workpiece includes silicon having a lattice structure, and wherein the porous region forms part of the lattice structure.

123. The system of claim 109 wherein the microfeature workpiece includes a memory chip.

124. A microfeature system, comprising:
a microfeature workpiece that includes:
a silicon substrate material having a first surface, a second surface facing away from the first surface, and a lattice structure between the first and second surfaces, the lattice structure including a porous region having a first part extending generally parallel to the first surface, a second part extending generally normal to the first surface, and a third part extending generally normal to the first surface; and
a conductive material disposed in pores of the porous region at the first, second and third parts to form a conductive path.

125. The system of claim 124, further comprising an insulating material at the surfaces of pores in the porous region.

126. The system of claim 124 wherein the porous region includes a plurality of interconnected pores having interconnected pore surfaces, and wherein the microfeature workpiece further comprises an oxide layer at the pore surfaces.

127. The system of claim 124 wherein the porous region includes a plurality of interconnected pores having interconnected pore surfaces, and wherein the conductive path includes interconnected conductive path segments positioned in the pores.

128. The system of claim 124, further comprising:
a bond pad; and
a microelectronic structure disposed in the substrate material, and wherein the conductive path is electrically connected to the microelectronic structure and the bond pad.

129. The system of claim 124, further comprising a bond pad coupled to the conductive path.

130. The system of claim 124 wherein the conductive path includes a first end region and a second end region, and wherein the system further comprises:
a first conductive element coupled to the conductive path toward the first end region; and
a second conductive element coupled to the conductive path toward the second end region.

131. The system of claim 124 wherein the conductive path extends through the microfeature workpiece from the first surface to the second surface.

132. The system of claim 124 wherein the microfeature workpiece includes a first microelectronic die, and wherein the system further comprises a second microelectronic die stacked on the first microelectronic die and electrically coupled to the conductive path of the first microelectronic die.

133. The system of claim 124 wherein the conductive material includes at least one of silver, copper, tin, lead, tungsten and aluminum.

134. The system of claim 124 wherein the porous region extends away from the first surface and has a dimension generally parallel to the first surface of one micron or less.

135. The system of claim 124 wherein the porous region includes:
a first part extending generally parallel to the first surface and offset from the first surface; and
second and third parts that extend generally transverse to the first surface, with the first part connected to and extending between the second and third parts.

136. The system of claim 124 wherein the microfeature workpiece includes a memory chip.
